(19) United States
(12) Patent Application Publication
(10) Pub. No.: US 2007/0296079 A1
(43) Pub. Date: Dec. 27, 2007

(54) Heat dissipating structure and method for fabricating the same

(75) Inventors: Chien-Ping Huang, Hsinchu Hsien (TW); Han-Ping Pu, Taichung Hsien (TW); Ho-Yi Tsai, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/818,225

(22) Filed: Jun. 12, 2007

(30) Foreign Application Priority Data
Jun. 12, 2006 (TW) 095120791

(51) Int. Cl. H01L 23/34; H01L 21/58

(52) U.S. Cl. 257/712; 438/122; 438/124; 257/787

(57) ABSTRACT

A heat sink package structure and a method for fabricating the same are disclosed. The method includes mounting and electrically connecting a semiconductor chip to a chip carrier, forming an interface layer or a second heat dissipating element having the interface layer on the semiconductor chip and installing a first heat dissipating element having a heat dissipating portion and a supporting portion onto the chip carrier. The method further includes forming openings corresponding to the semiconductor chip in the heat dissipating portion, and forming an encapsulant for covering the semiconductor chip, the interface layer or the second heat dissipating element, and the first heat dissipating element. A height is reserved on top of the interface layer for the formation of the encapsulant for covering the interface layer. The method further includes cutting the encapsulant along edges of the interface layer, and removing the redundant encapsulant on the interface layer. Therefore, the drawbacks of the prior art of the burrs caused by a cutting tool for cutting the heat dissipating element and wearing of the cutting tool are overcome.

### BACKGROUND OF THE INVENTION

1. Field of the Invention

The present invention relates generally to semiconductor package structures and method for fabricating the same, and more particularly to heat sink semiconductor package structures that can efficiently dissipate heat produced by semiconductor chips and method for fabricating the same.

2. Description of Related Art

Along with demands for lighter, thinner, smaller and shorter electronic products, semiconductor chip packages integrating high-density electronic components and electronic circuits have become a mainstream. Such packages in operation produce a large amount of heat. The heat must be dissipated timely. Otherwise, electric performance of semiconductor chips and product stability can be seriously affected. On the other hand, in order to protect internal circuits of semiconductor packages from mist and dust pollution, semiconductor chip surfaces are generally covered by encapsulants. As the encapsulants are generally made of a material having low heat conductivity such as only 0.8 w/m-° K., heat generated from active surfaces of semiconductor chips are difficult to be efficiently dissipated to the exterior, thereby adversely affecting electric performance and lifetime of the semiconductor chips. As a result, heat dissipating elements are disposed in semiconductor packages for improving heat dissipating efficiency.

If heat dissipating elements inside semiconductor packages are completely encapsulated by encapsulants, the heat dissipating path still needs to pass through the encapsulant and the heat dissipating efficiency is limited. Therefore, it is benefited by exposing surfaces of heat dissipating elements or semiconductor chips from encapsulants to efficiently dissipate heat of semiconductor packages.

FIG. 1A shows a semiconductor package 10 disclosed by U.S. Pat. No. 5,450,283, wherein top surface of the semiconductor chip 11 is directly exposed from an encapsulant 14 such that heat produced by the semiconductor chip 11 can be mostly dissipated to the atmosphere directly without the need of passing through the encapsulant 14, thereby improving heat dissipating efficiency of the semiconductor package 10.

However, some drawbacks exist in fabricating the semiconductor package 10. Please referring to FIG. 1B, firstly, when the substrate 12 with the semiconductor chip 11 adhered thereto is disposed inside a mold cavity 15 to perform a molding process for forming the encapsulant 14, a tape 13 is provided and attached to the top wall of the mold cavity 15 such that the top surface of the semiconductor chip 11 can be abutted against the top wall of the mold cavity 15 through the tape 13 after the mold is engaged, thereby preventing overflow of the encapsulant on the top surface of the semiconductor chip 11. However, it is difficult to precisely control the mounting height of the semiconductor chip 11 to the substrate 12 so as to make the top surface of the semiconductor chip 11 precisely abut against the top wall of the mold cavity 15. The total height of the substrate 12 with the semiconductor chip 11 adhered thereto can be too low or too high. If the total height of the substrate 12 with the semiconductor chip 11 adhered thereto is too low, a gap exists between the top surface of the semiconductor chip 11 and the top wall of the mold cavity 15. As a result, the overflow of the encapsulant is formed on the top surface of the semiconductor chip 11, which adversely affects the heat dissipating efficiency of the semiconductor chip 11 and the product appearance. As a result, a deflash process is needed for removing the overflow of the encapsulant on the top surface of the semiconductor chip 11, which not only increases the fabrication time and the fabrication cost, but also may lead to product damage. On the other hand, if the total height of the substrate 12 with the semiconductor chip 11 adhered thereto is too high, too strong abutting force is induced between the top surface of the semiconductor chip 11 and the top wall of the mold cavity 15 and result in cracking of the semiconductor chip 11.

According to the above drawbacks, U.S. Pat. No. 6,750,082 discloses another kind of semiconductor package, which removes the encapsulant covering the semiconductor chip through a grinding method so as to expose the surface of the semiconductor chip from the encapsulant. However, the grinding method needs a high cost. In addition, warpage of the semiconductor package can occur due to a mismatch of coefficient of thermal expansion between the encapsulant and the heat sink or semiconductor chip, thus increasing difficulty of efficiently exposing surface of the semiconductor chip. Also, the grinding forces may cause cracking of the semiconductor chip.

Accordingly, U.S. Pat. No. 6,458,626, as shown in FIGS. 2A to 2C, No. 6,444,498, as shown in FIG. 3, and No. 6,699,731, as shown in FIG. 4, patentees of which are applicant of the present application, respectively disclose semiconductor packages that directly adhere heat dissipating elements to semiconductor chips without causing cracking of the semiconductor chips or overflow problems, or directly expose surfaces of the semiconductor chips from the semiconductor packages.

As shown in FIG. 2A, an interface layer 25 is formed on one surface of a heat dissipating element 21 to be exposed to the atmosphere, which has a low adhesion force with the encapsulant 24. Then, the heat dissipating element 21 having the interface layer 25 is mounted on a semiconductor chip 20 of a substrate 23 through the other surface thereof. Subsequently, a molding process is performed so as to form an encapsulant 24 encapsulating the semiconductor chip 20, the heat dissipating member 21 and the interface layer 25 of the heat dissipating element 21, as shown in FIG. 2A. Thus, the depth of the mold cavity can be made bigger than the total thicknesses of the semiconductor chip 20 and the heat dissipating element 21. Therefore, after the engagement of the mold, the mold does not contact the heat dissipating element 21. Thus the semiconductor chip 20 can be protected from damage. Then, as shown in FIGS. 2B and 2C, a cutting process is performed and the encapsulant 24 located on the heat dissipating element 21 is removed. Therein, if the adhesion between the interface layer 25 such as a gold plated layer and the heat dissipating element 21 is bigger than that between the interface layer 25 and the encapsulant 24, the encapsulant 24 can be thoroughly removed through the removing process while the interface layer 25 is left on the heat dissipating element 21, thus overcoming the conventional overflow problem. On the other hand, if the adhesion between the interface layer 25 such as a P.I. tape and the encapsulant 24 is bigger than that between the interface layer 25 and the heat dissipating element 21, both the encapsulant 24 and the interface layer 25 are removed through the removing process, as shown in FIG. 3, which also overcomes the conventional overflow problem.

Alternatively, as shown in FIG. 4, a covering plate 33 having an interface layer 333 is formed on the semiconductor chip 31. The covering plate 33 may be made of a metal material. As the coefficient of thermal expansion of the encapsulant 34 is different from that of the interface layer 333 of the covering plate 33, delamination occurs between the interface layer 333 with low adhesion and the semiconductor chip 31 as well as the encapsulant 34 around the semiconductor chip 31, which facilitates the removal of the interface layer 333, the covering plate 33, and the encapsulating compound 340 formed on the covering plate 33 from the semiconductor chip 31 and the encapsulant 34 around the semiconductor chip 31. As a result, heat generated from the semiconductor chip 31 can be dissipated to the outside directly. Meanwhile, in the molding process, as the surface of the semiconductor chip 31 is completely covered by the interface layer 333 of the covering plate 33, there is no encapsulant formed thereon, thereby eliminating the need of deflashing process and reducing the packaging cost. In addition, the package appearance is improved.

However, during the above cutting process, cutting tools need to pass through the heat dissipating elements. As the heat dissipating elements are generally made of a metal material such as copper and aluminum, when a diamond cutting tool passes through the heat dissipating elements, rough edges or burrs can be formed on periphery of the heat dissipating elements, thereby adversely affecting the product appearance and causing wearing of the cutting tool.

Therefore, there is a need to provide a heat sink package structure and method for fabricating the same, which can overcome the above drawbacks.

### SUMMARY OF THE INVENTION

According to the above drawbacks, an objective of the present invention is to provide a heat sink package structure and method for fabricating the same, which can protect the semiconductor chip from being damaged during the molding process.

Another objective of the present invention is to provide a heat sink package structure and method for fabricating the same, through which the semiconductor chip can be exposed without using the grinding method, thereby avoiding the cracking of the semiconductor chip and reducing the fabrication cost.

A further objective of the present invention is to provide a heat sink package structure and method for fabricating the same, through which the conventional burr problem and wearing of the cutting tools can be prevented so as to reduce the cutting cost.

In order to attain the above and other objectives, a fabrication method of a heat sink package structure is disclosed by the present invention, which comprises the steps of: mounting a semiconductor chip to a chip carrier through one surface thereof, electrically connecting the semiconductor chip to the chip carrier, and forming an interface layer on the other surface of the semiconductor chip; mounting a first heat dissipating element on the chip carrier, wherein the first heat dissipating element comprises a heat dissipating portion, a supporting portion extending downward from the heat dissipating portion, and an opening formed in the heat dissipating portion, the first heat dissipating element is mounted on the chip carrier through the supporting portion thereof, and meanwhile the semiconductor chip is received in the receiving portion constituted by the heat dissipating portion and the supporting portion of the first heat dissipating element, the interface layer being received in the opening of the heat dissipating portion; performing a molding process so as to form an encapsulant encapsulating the semiconductor chip, the interface layer and the first heat dissipating element, wherein the upper surface of the heat dissipating portion of the first heat dissipating element is exposed from the encapsulant; cutting the encapsulant along edges of the interface layer, wherein the cutting depth reaches at least the same level as the position of the interface layer; and performing a removing process for removing the encapsulant located on the interface layer.

The interface layer can be made of a material such as a P.I. tape, an epoxy resin, or an organic layer, which makes the adhesion between the interface layer and the encapsulant greater than that between the interface layer and the semiconductor chip such that both the interface layer and the encapsulant located on the interface layer can be removed through the removing process for exposing the surface of the semiconductor chip for heat dissipation. Further, an external heat dissipating element can be disposed on the exposed surface of the semiconductor chip. On the other hand, the interface layer can be made of a material such as Au or Ni, which makes the adhesion between the interface layer and the semiconductor chip greater than that between the interface layer and the encapsulant such that only the encapsulant located on the interface layer is removed through the removing process so as to expose the interface layer, thereby efficiently dissipating the heat produced by the semiconductor chip to the exterior through the interface layer.

Another method for fabricating the heat sink package structure of the present invention comprises the steps of: mounting a semiconductor chip to a chip carrier through one surface thereof, electrically connecting the semiconductor chip to the chip carrier, and disposing a second heat dissipating element with an interface layer on the other surface of the semiconductor chip; mounting a first heat dissipating element on the chip carrier, wherein the first heat dissipating element comprises a heat dissipating portion, a supporting portion extending downward from the heat dissipating portion, and an opening formed in the heat dissipating portion, the first heat dissipating element is mounted on the chip carrier through the supporting portion thereof, and meanwhile the semiconductor chip is received in the receiving portion constituted by the heat dissipating portion and the supporting portion of the first heat dissipating element, the interface layer being received in the opening of the heat dissipating portion; performing a molding process so as to form an encapsulant encapsulating the semiconductor chip, the interface layer, the first and second heat dissipating elements, wherein the upper surface of the heat dissipating portion of the first heat dissipating element is exposed from the encapsulant; cutting the encapsulant along edges of the interface layer, wherein the cutting depth reaches at least the same level as the position of the interface layer; and performing a removing process for removing the encapsulant located on the interface layer.

The interface layer can be made of a material such as a P.I. tape, an epoxy resin, or an organic layer, which makes the adhesion between the interface layer and the encapsulant greater than that between the interface layer and the second heat dissipating element such that both the interface layer and the encapsulant located on the interface layer can be removed through the removing process for exposing the surface of the second heat dissipating element for heat dissipation. On the other hand, the interface layer can be a metal layer made of such as Au or Ni, which makes the adhesion between the interface layer and the second heat dissipating element greater than that between the interface layer and the encapsulant such that only the encapsulant located on the interface layer is removed through the removing process so as to expose the interface layer, thereby dissipating the heat produced by the semiconductor chip to the exterior through the heat dissipating element and the interface layer.

The chip carrier can be a substrate or a leadframe, and the semiconductor chip can be electrically connected to the chip carrier through a flip-chip method or a wire bonding method. If the semiconductor chip is electrically connected to the chip carrier through the flip-chip method, the interface layer or the second heat dissipating element having the interface layer can be directly disposed on the non-active surface of the semiconductor chip. On the other hand, if the semiconductor chip is electrically connected to the chip carrier through bonding wires, a material layer such as a scraped chip or a heat dissipating element can be disposed on the active surface of the semiconductor chip at a position without affecting the bonding wires and then the interface layer or the second heat dissipating element having the interface layer is disposed on the material layer.

Through the above methods, a heat sink package structure is disclosed, comprising: a chip carrier; a semiconductor chip mounted to and electrically connected to the chip carrier; a first heat dissipating element comprising a heat dissipating portion, a supporting portion extending downward from the heat dissipating portion, and an opening formed in the heat dissipating portion, wherein the first heat dissipating element is mounted on the chip carrier through the supporting portion thereof, and the semiconductor chip is received in the receiving portion constituted by the heat dissipating portion and the supporting portion of the first heat dissipating element; and an encapsulant formed on the chip carrier for encapsulating the semiconductor chip and the first heat dissipating element, wherein a recess structure is formed in the encapsulant corresponding in position to the opening of the heat dissipating portion of the first heat dissipating element so as to expose the upper surface of the semiconductor chip.

Therefore, the heat sink package structure and method for fabricating the same mainly mounting and electrically connecting a semiconductor chip to a chip carrier; mounting an interface layer or a second heat dissipating element having an interface layer on the semiconductor chip; disposing a first heat dissipating element having a heat dissipating portion and a supporting portion on the chip carrier, wherein the heat dissipating portion has an opening formed corresponding to the semiconductor chip; forming an encapsulant that encapsulates the semiconductor chip, the interface layer or the second heat dissipating element having the interface layer, and the first heat dissipating element, wherein a height is reserved on top of the interface layer for the formation of the encapsulant for covering the interface layer, thereby preventing cracking of the semiconductor chip during the molding process; subsequently, cutting the encapsulant along edges of the interface layer or the heat dissipating element having the interface layer; and removing the encapsulant located on the interface layer, wherein, the interface layer can be removed together with the encapsulant located on the interface layer or left on. Thus, a heat sink package structure is formed without using the conventional grinding method, thereby avoiding the cracking of the semiconductor chip in grinding the encapsulant of the prior art. Meanwhile, since the cutting line does not pass through the heat dissipating element, the burr problem and wearing of cutting tools can be prevented and accordingly the cutting cost can be reduced.

### BRIEF DESCRIPTION OF DRAWINGS

FIGS. 1A and 1B are sectional diagrams of a semiconductor package disclosed by U.S. Pat. No. 5,450,283;

FIGS. 2A to 2C are sectional diagrams of a semiconductor package disclosed by U.S. Pat. No. 6,458,626;

FIG. 3 is a sectional diagram of a semiconductor package disclosed by U.S. Pat. No. 6,444,498;

FIG. 4 is a sectional diagram of a semiconductor package disclosed by U.S. Pat. No. 6,699,731;

FIGS. 5A to 5F are diagrams showing a heat sink package structure and method for fabricating the same according to a first embodiment of the present invention;

FIGS. 6A and 6B are diagrams showing a heat sink package structure and method for fabricating the same according to a second embodiment of the present invention;

FIG. 7 is a diagram of a heat sink package structure according to a third embodiment of the present invention;

FIG. 8 is a diagram of a heat sink package structure according to a fourth embodiment of the present invention;

FIGS. 9A to 9E are diagrams showing a heat sink package structure and method for fabricating the same according to a fifth embodiment of the present invention;

FIG. 10 is a diagram of a heat sink package structure according to a sixth embodiment of the present invention;

FIG. 11 is a diagram of a heat sink package structure according to a seventh embodiment of the present invention; and

FIGS. 12A and 12B are diagrams of a heat sink package structure according to an eighth embodiment of the present invention.

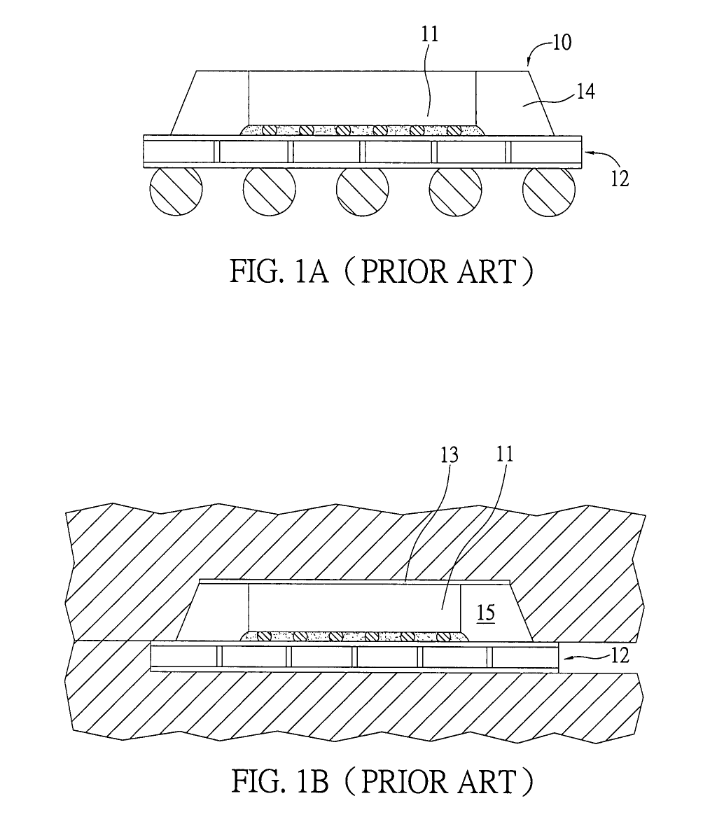

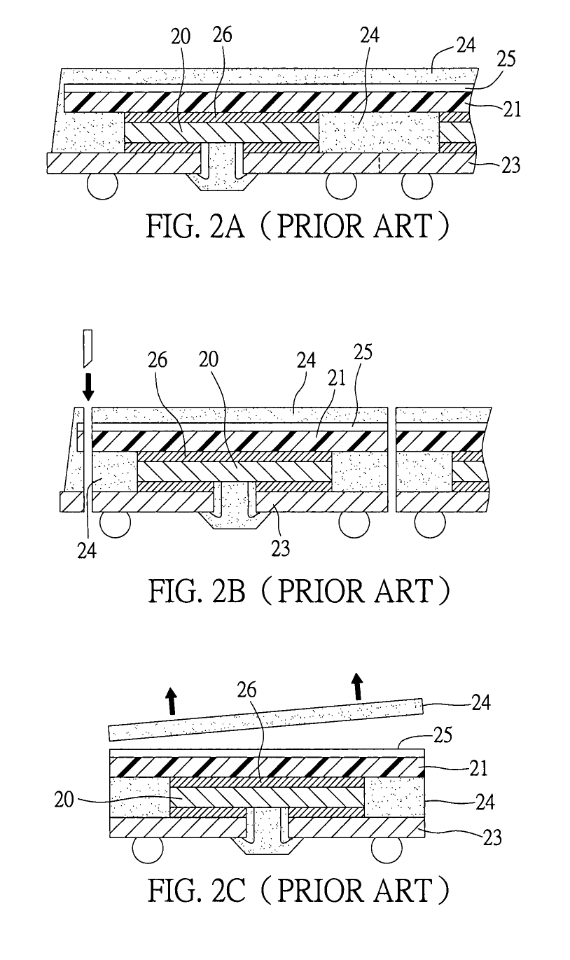

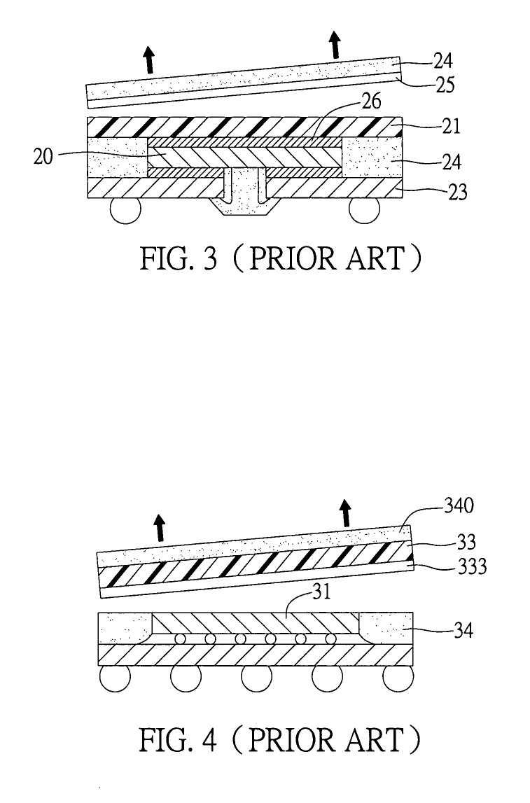

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

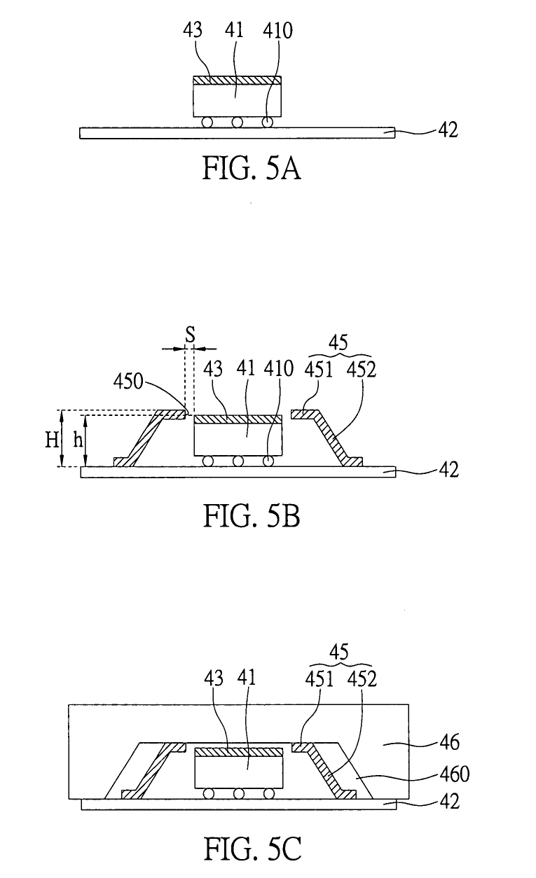

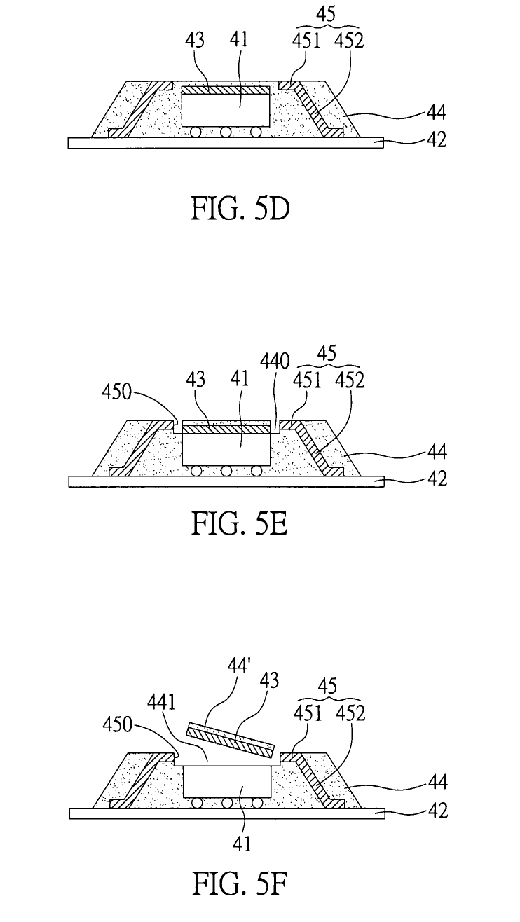

FIGS. 5A to 5F are diagrams showing a heat sink package structure and method for fabricating the same according to a first embodiment of the present invention.

As shown in FIG. 5A, a semiconductor chip 41 is mounted to and electrically connected to a chip carrier 42 through one surface thereof, and an interface layer 43 is formed on the other surface of the semiconductor chip 41.

The chip carrier 42 may be a BGA substrate or an LGA substrate. The semiconductor chip 41 may be such as a flip-chip semiconductor chip, the active surface of which is electrically connected to the chip carrier 42 through a plurality of conductive bumps 410.

The interface layer 43 may be a P.I. tape adhered to the semiconductor chip 41, or an epoxy resin coated on semiconductor chip 41, or an organic layer made of such as wax formed on the semiconductor chip 41. Thus, the adhesion between the interface layer 43 and the encapsulant to be formed subsequently for encapsulating the semiconductor chip 41 is bigger than that between the interface layer 43 and the semiconductor chip 41. Therefore, the interface layer and the encapsulant located on the interface layer can easily be removed from the semiconductor chip 41.

As shown in FIG. 5B, a first heat dissipating element 45 is disposed on the chip carrier 42. The first heat dissipating element 45 comprises a heat dissipating portion 451, a supporting portion 452 extending downward from the heat dissipating portion 451, and an opening 450 formed in the heat dissipating portion 451. The first heat dissipating element 45 is disposed on the chip carrier 42 through the supporting portion 452 thereof. Meanwhile, the semiconductor chip 41 is received in the receiving space constituted by the heat dissipating portion 451 and the supporting portion 452, and the interface layer 43 is received in the opening 450 of the heat dissipating portion 451. Size of the opening 450 is greater than that of the semiconductor chip 41 and the interface layer 43. The distance S between the opening and the interface layer is about 0.05 to 0.3 mm, and preferably 0.1 mm. Height H of the first heat dissipating element 45 is about 0.1 to 0.3 mm higher than height h of the interface layer 43.

As shown in FIGS. 5C and 5D, the chip carrier 42 integrated with the semiconductor chip 41, the interface layer 43 and the first heat dissipating element 45 is disposed in a mold cavity 460 of a packaging mold 46 such that a molding process can be performed. As shown in FIG. 5D, after the packaging mold 46 is removed, an encapsulant 44 encapsulating the interface layer 43, the semiconductor chip 41 and the first heat dissipating element 45 is formed on the chip carrier 42, and meanwhile the upper surface of the heat dissipating portion 451 of the first heat dissipating element 45 is exposed from the encapsulant 44. Therein, height of the heat dissipating portion 451 of the first heat dissipating element 45 is 0.05 to 0.1 mm higher than depth of the mold cavity 460 of the packaging mold 46. Therefore, the interface layer 43 is at least 0.05 mm (0.15 mm-0.1 mm=0.05 mm) smaller than the depth of the mold cavity 460. During the molding process, because the height of the heat dissipating portion 451 of the first heat dissipating element 45 is 0.05 to 0.1 mm bigger than the depth of the mold cavity 460 of the packaging mold 46, the first heat dissipating element 45 can be abutted against the mold cavity 460 of the packaging mold 46 and compressed about 0.05 to 0.1 mm. As a result, the overflow of encapsulant is prevented. In addition, as the height of the interface layer 43 is smaller than the depth of the mold cavity 460, after the mold is engaged, the semiconductor chip 41 is prevented from suffering the pressure from the packaging mold 46, thereby improving the product yield and the product reliability.

As shown in FIG. 5E, a laser cutting process can be performed to cut the encapsulant 44 formed in the gap between the interface layer 43 and the opening 450 of the heat dissipating portion 451 so as to form a recess 440. The bottom of the recess 440 should at least be at the same level as the interface layer 43. Preferably, the bottom of the recess 440 is 0.05 to 0.1 mm deeper than the interface layer 43. In addition, the distance from the recess 440 to the interface layer 43 is in a range of 0 to 0.1 mm, and preferably 0.05 mm. Alternatively, the recess 440 can extend into the interface layer 43 about 0.1 mm, preferably 0.05 mm. Since the cutting process is performed around the interface layer 43 instead of directly cutting through the heat dissipating element as in the conventional art, the burr problem and wearing of the cutting tools can be avoided in the present invention, thereby reducing the cutting cost.

As shown in FIG. 5F, a removing process is performed so as to remove the interface layer 43 and the encapsulant 44′ located on the interface layer 43. Thus, a recess structure 441 is formed in the encapsulant 44 corresponding in position to the semiconductor chip 41 so as to expose the top surface of the semiconductor chip 41 from the encapsulant 44.

Through the above fabrication method, a semiconductor package structure is obtained, which comprises: a chip carrier 42; a semiconductor chip 41 mounted to and electrically connected to the chip carrier 42; a first heat dissipating element 45 having a heat dissipating portion 451, a supporting portion 452 extending downward from the heat dissipating portion 451, and the an opening 450 formed in the heat dissipating portion 451, the first heat dissipating element 45 being disposed on the chip carrier 42 through the supporting portion 451 thereof and the semiconductor chip 41 being received in the receiving space constituted by the heat dissipating portion 451 and the supporting portion 452; and an encapsulant 44 formed on the chip carrier 42 for encapsulating the semiconductor chip 41 and the first heat dissipating element 45, wherein the encapsulant 44 has a recess structure 441 formed corresponding in position to the semiconductor chip 41 so as to expose the top surface of the semiconductor chip 41 from the encapsulant 44. Thus, heat produced by the semiconductor chip 41 can be efficiently dissipated to the exterior of the package.

### Second Embodiment

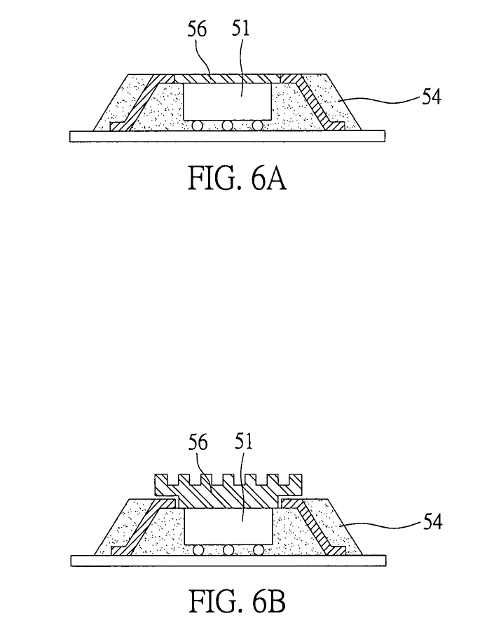

FIGS. 6A and 6B are sectional diagrams of a heat sink package structure according to a second embodiment of the present invention. In the present embodiment, an external heat slug 56 is disposed on the exposed surface of the semiconductor chip 51. As shown in FIG. 6A, the external heat slug 56 has shape of a flat plate. In addition, as shown in FIG. 6B, a plurality of fins can be formed on the external heat slug 56 for improving heat dissipating efficiency.

### Third Embodiment

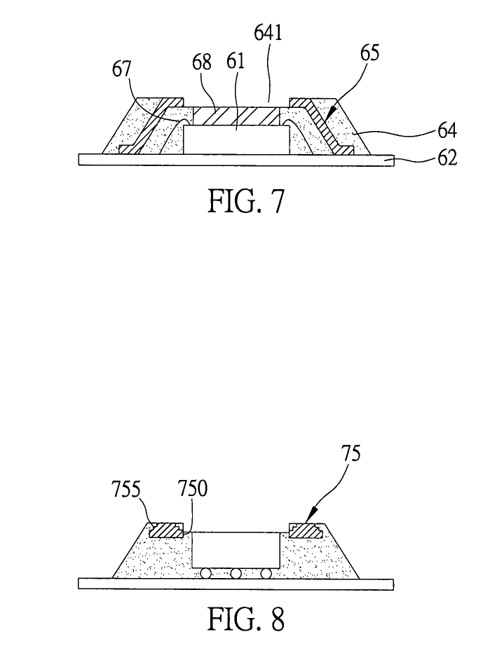

FIG. 7 is a sectional diagram showing a heat sink package structure according to a third embodiment of the present invention. In the present embodiment, a wire-bonding semiconductor chip 61 is mounted to a chip carrier 62 through its non-active surface, and electrically connected with the chip carrier 62 through a plurality of bonding wires 67. A material layer 68 such as a scraped chip or a heat dissipating element is mounted on the active surface of the semiconductor chip 61. Further, an interface layer (not shown) is mounted on the material layer 68. Thus, after the first heat dissipating element 65 is disposed on the chip carrier 62 and the molding process is performed, both the interface layer and the encapsulant on the interface layer can be removed so as to form a recess structure 641 for exposing the material layer 68 from the encapsulant 64, thereby increasing heat dissipating efficiency of the semiconductor chip 61.

It should be noted that the material layer 66 should be positioned on the semiconductor chip 61 without interfering the bonding wires 67, and thickness of the material layer 66 should be slightly higher than the highest point of arcs of the bonding wires 67.

Fourth Embodiment

FIG. 8 is a diagram of a heat sink package structure according to a fourth embodiment of the present invention. The main difference of the present embodiment from the embodiments mentioned above is stepped structures 755 are formed at edge of the opening 750 and even at lateral sides of the heat dissipating portion of the first heat dissipating element 75, which can be used to control the overflow of the encapsulant during the molding process.

### Fifth Embodiment

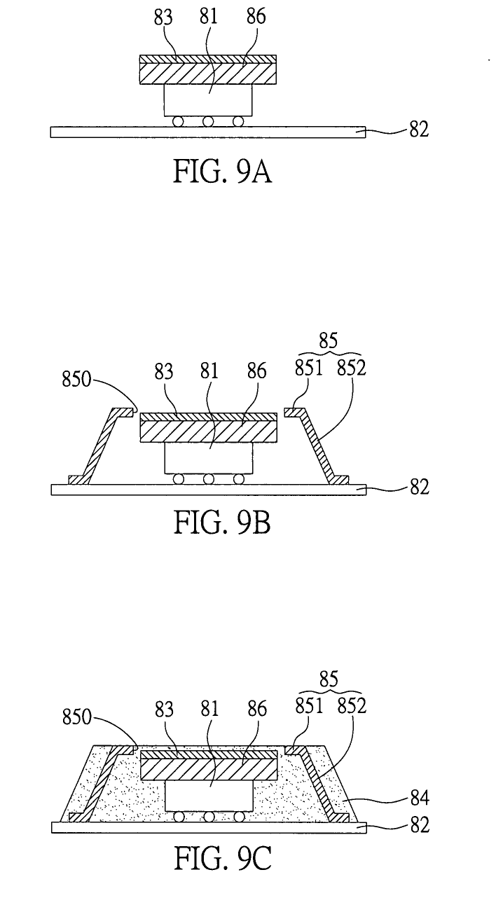

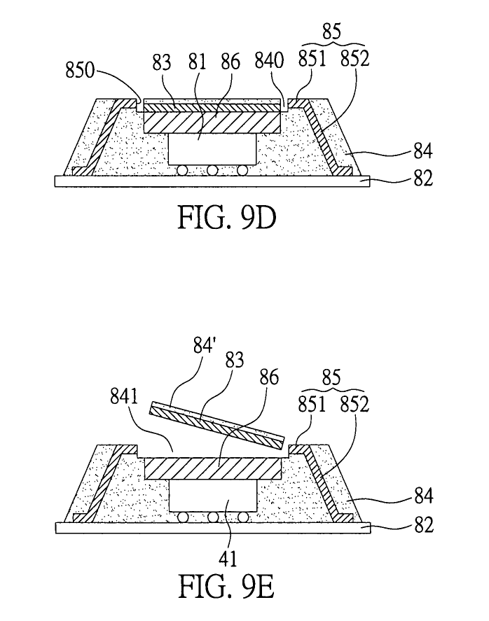

FIGS. 9A to 9E are diagrams showing a heat sink package structure and method for fabricating the same according to a fifth embodiment of the present invention.

As shown in FIG. 9A, a semiconductor chip 81 is mounted and electrically connected to a chip carrier 82. A second heat dissipating element 86 having an interface layer 83 formed on one surface thereof is disposed on the semiconductor chip 81 through the other surface thereof. Therein, planar size of the second heat dissipating element 86 is bigger than or equal to planar size of the semiconductor chip 81.

As shown in FIG. 9B, a first heat dissipating element 85 is disposed on the chip carrier 82, which comprises a heat dissipating portion 851, a supporting portion 852 extending downward from the heat dissipating portion 851, and an opening 850 formed in the heat dissipating portion 851. The first heat dissipating element 85 is disposed on the chip carrier 82 through the supporting portion 852 thereof. Meanwhile, the semiconductor chip 81 is received in the receiving space constituted by the heat dissipating portion 851 and the supporting portion 852, and the interface layer 83 is received in the opening 850 of the heat dissipating portion 851. Size of the opening 850 is bigger than that of the semiconductor chip 81 and the interface layer 83. Height of the first heat dissipating element 85 is higher than that of the interface layer 83.

As shown in FIG. 9C, a molding process is performed so as to form an encapsulant 84 encapsulating the semiconductor chip 81, the interface layer 83, the first and second heat dissipating elements 85,86. Meanwhile, the heat dissipating portion 851 of the first heat dissipating element 85 is exposed from the encapsulant 84.

As shown in FIG. 9D, the encapsulant 84 formed in the gap between the interface layer 83 and the opening 850 of the heat dissipating portion 851 is cut so as to form a recess 840.

As shown in FIG. 9E, a removing process is performed for removing the interface layer 83 and the encapsulant 84′ located on the interface layer 83. Therein, the interface layer 83 may be made of an organic material such as a tape, an epoxy resin or a wax so as to make the adhering between the interface layer 83 and the encapsulant 84 bigger than that between the interface layer 83 and the second heat dissipating element 86, thereby facilitating the removal of the interface layer 83 and the encapsulant 84′ located on the interface layer 83. As a result, a recess structure 841 is formed in the encapsulant 84 for exposing the top surface of the second heat dissipating element 86 from the encapsulant 84 for dissipating heat of the semiconductor chip 81.

### Sixth Embodiment

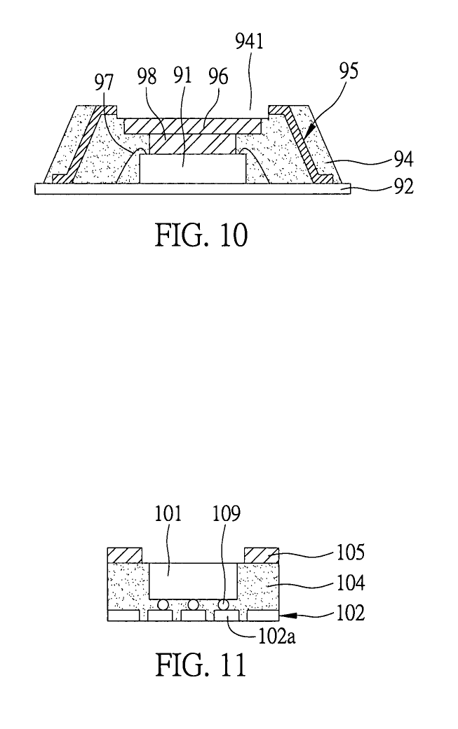

FIG. 10 is a diagram of a heat sink package structure according to a sixth embodiment of the present invention. The main difference of the present embodiment from the fifth embodiment is a wire-bonding semiconductor chip 91 is mounted to a chip carrier 92 through its non-active surface, and electrically connected with the chip carrier 92 through a plurality of bonding wires 97. A material layer 98 such as a scraped chip or a heat dissipating element is mounted on the active surface of the semiconductor chip 91. Further, a second heat dissipating element 96 and an interface layer (not shown) are mounted on the material layer 98 such that after the first heat dissipating element 95 is disposed on the chip carrier 92 and the molding process is finished, a cutting process can be performed to remove the interface layer and the encapsulant located on the interface layer for forming a recess structure 941, thereby exposing the second heat dissipating element 96 from the encapsulant 94 for improving heat dissipating efficiency of the semiconductor chip 91.

### Seventh Embodiment

FIG. 11 is a diagram of a heat sink package structure according to a seventh embodiment of the present invention. As shown in FIG. 11, a QFN leadframe 102 is used as the chip carrier of the semiconductor chip 101. The active surface of the semiconductor chip 101 is mounted to leads 102a of the QFN leadframe 102 through a plurality of conductive bumps 109. An interface layer (not shown) is disposed on the non-active surface of the semiconductor chip 101, and a first heat dissipating element 105 is disposed on the leadframe 102. Then, a molding process, a cutting process and a removing process are performed for removing the interface layer and the encapsulant on the interface layer for exposing the non-active surface of the semiconductor chip from the encapsulant 104.

### Eighth Embodiment

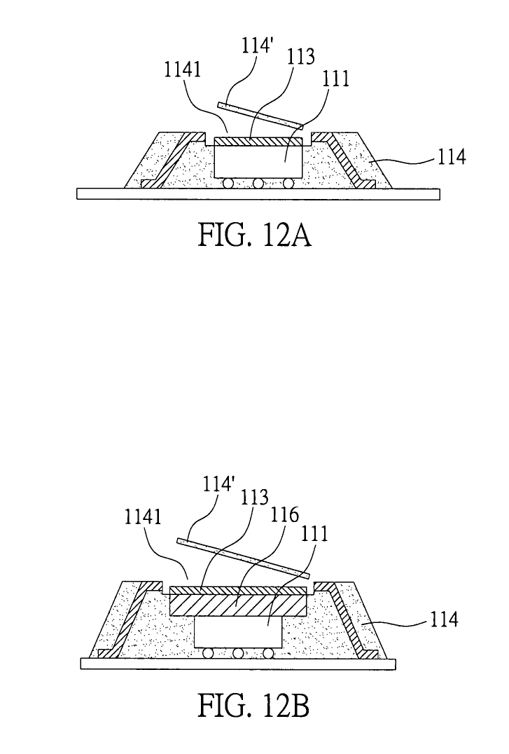

FIGS. 12A and 12B are diagrams of a heat sink package structure according to an eighth embodiment of the present invention.

As shown in FIG. 12A, the interface layer 113 is made of a metal layer such as Au or Ni, which makes the adhesion between the interface layer 113 and the semiconductor chip 111 bigger than that between the interface layer 113 and the encapsulant 114. Therefore, the encapsulant 114′ located on the interface layer 113 is removed through a removing process while the interface layer 113 is left on the semiconductor chip 111, thus forming a recess structure 1141 with the interface layer 113 exposed from the encapsulant 114. Heat produced by the semiconductor chip 111 can be dissipated to the exterior through the interface layer 113.

Alternatively, as shown in FIG. 12B, a second heat dissipating element 116 having an interface layer 113 is disposed on the semiconductor chip 111. The interface layer 113 is made of a metal layer such as Au or Ni so as to make the adhesion between the interface layer 113 and the second heat dissipating element 116 bigger than that between the interface layer 113 and the encapsulant 114. As a result, the encapsulant 114′ located on the interface layer 113 can be removed through a removing process while the interface layer 113 is left on the second heat dissipating element 116, thus forming a recess structure 1141 with the interface layer 113 exposed from the encapsulant 114. Heat produced by the semiconductor chip 111 can be dissipated to the exterior through the second heat dissipating element 116 and the interface layer 113.

Therefore, the heat sink package structure and method for fabricating the same mainly comprises the steps of mounting and electrically connecting a semiconductor chip to a chip carrier; mounting an interface layer or a second heat dissipating element having an interface layer on the semiconductor chip; disposing a first heat dissipating element having a heat dissipating portion and a supporting portion on the chip carrier, wherein the heat dissipating portion has an opening formed corresponding to the semiconductor chip; forming an encapsulant that encapsulates the semiconductor chip, the interface layer or the second heat dissipating element having the interface layer, and the first heat dissipating element, wherein a height is reserved on top of the interface layer for the formation of the encapsulant for covering the interface layer, thereby preventing cracking of the semiconductor chip during the molding process; subsequently, cutting the encapsulant along edges of the interface layer or the heat dissipating element having the interface layer; and removing the encapsulant located on the interface layer, wherein, the interface layer can be removed together with the encapsulant located on the interface layer or left on. Thus, a heat sink package structure is formed without using the conventional grinding method, thereby avoiding the cracking of the semiconductor chip in grinding the encapsulant of the prior art. Meanwhile, since the cutting line does not pass through the heat dissipating element, the burr problem and wearing of cutting tools can be prevented and accordingly the cutting cost can be reduced.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A method for fabricating a heat sink package structure, comprising the steps of:
mounting a semiconductor chip to a chip carrier through one surface thereof, electrically connecting the semiconductor chip to the chip carrier, and forming an interface layer on the other surface of the semiconductor chip;
mounting a first heat dissipating element on the chip carrier, wherein the first heat dissipating element comprises a heat dissipating portion, a supporting portion extending downward from the heat dissipating portion, and an opening formed in the heat dissipating portion, the first heat dissipating element is mounted on the chip carrier through the supporting portion thereof, and meanwhile the semiconductor chip is received in the receiving portion constituted by the heat dissipating portion and the supporting portion of the first heat dissipating element, the interface layer being received in the opening of the heat dissipating portion;
performing a molding process so as to form an encapsulant encapsulating the semiconductor chip, the interface layer and the first heat dissipating element, wherein the upper surface of the heat dissipating portion of the first heat dissipating element is exposed from the encapsulant;
cutting the encapsulant along edges of the interface layer, wherein the cutting depth reaches at least the same level as the position of the interface layer; and
performing a removing process for removing the encapsulant located on the interface layer.

2. The method of claim 1, wherein the chip carrier is one of a substrate and a leadframe, and the semiconductor chip is electrically connected to the chip carrier through one of a flip-chip method and a wire bonding method.

3. The method of claim 2, wherein if the semiconductor chip is electrically connected to the chip carrier through the flip-chip method, the interface layer is directly disposed on the non-active surface of the semiconductor chip; on the other hand, if the semiconductor chip is electrically connected to the chip carrier through bonding wires, a material layer can be disposed on the active surface of the semiconductor chip and then the interface layer is disposed on the material layer.

4. The method of claim 3, wherein the material layer is one of a scraped chip and a heat dissipating element.

5. The method of claim 3, wherein the material layer is exposed from the encapsulant so as to improve the heat dissipating efficiency of the semiconductor chip.

6. The method of claim 1, wherein the interface layer can be made of a material which makes the adhesion between the interface layer and the encapsulant greater than that between the interface layer and the semiconductor chip such that both the interface layer and the encapsulant located on the interface layer can be removed through the removing process for exposing the surface of the semiconductor chip for heat dissipation.

7. The method of claim 6, wherein the interface layer is one of a tape, an epoxy resin and an organic layer.

8. The method of claim 6, further comprising disposing an external heat dissipating element on the exposed surface of the semiconductor chip.

9. The method of claim 1, wherein the interface layer is made of a material which makes the adhesion between the interface layer and the semiconductor chip greater than that between the interface layer and the encapsulant such that only the encapsulant located on the interface layer is removed through the removing process so as to expose the interface layer.

10. The method of claim 9, wherein the interface layer is a metal layer.

11. The method of claim 1, wherein the heat dissipating portion of the first heat dissipating element is 0.1 to 0.3 mm higher than the interface layer, and preferably, the heat dissipating portion of the first heat dissipating element is 0.15 mm higher than the interface layer.

12. The method of claim 1, wherein during the molding process, the chip carrier integrated with the semiconductor chip, the first heat dissipating element and the interface layer is disposed inside a mold cavity of a packaging mold so as to form the encapsulant, wherein the height of the heat dissipating portion of the first heat dissipating element is 0.05 to 0.1 mm greater than the depth of the mold cavity of the packaging mold, and correspondingly the interface layer is lower than the depth of the mold cavity, therefore, the first heat dissipating element can be abutted against the mold cavity of the packaging mold and compressed 0.05 to 0.1 mm.

13. The method of claim 1, wherein by cutting the encapsulant around the interface layer, a recess is formed, depth of which is at least at the same level as the interface layer, and is preferably 0.05 to 0.1 mm deeper than the interface layer.

14. The method of claim 1, wherein by cutting the encapsulant around the interface layer, a recess is formed, spacing between the recess and the interface layer is less than 0.1 mm, preferably 0.05 mm.

15. The method of claim 1, wherein by cutting the encapsulant around the interface layer, a recess is formed, which can extend into the interface layer less than 0.1 mm, preferably 0.05 mm.

16. The method of claim 1, wherein the size of the opening is greater than that of the interface layer, and the distance therebetween is 0.05 to 0.3 mm, preferably 0.1 mm.

17. The method of claim 1, the opening and lateral sides of the heat dissipating portion of the first heat dissipating element have stepped structure.

18. A method for fabricating a heat sink package structure, comprising the steps of:
mounting a semiconductor chip to a chip carrier through one surface thereof, electrically connecting the semiconductor chip to the chip carrier, and disposing a second heat dissipating element with an interface layer on the other surface of the semiconductor chip;
mounting a first heat dissipating element on the chip carrier, wherein the first heat dissipating element comprises a heat dissipating portion, a supporting portion extending downward from the heat dissipating portion, and an opening formed in the heat dissipating portion, the first heat dissipating element is mounted on the chip carrier through the supporting portion thereof, and meanwhile the semiconductor chip is received in the receiving portion constituted by the heat dissipating portion and the supporting portion of the first heat dissipating element, the interface layer being received in the opening of the heat dissipating portion;
performing a molding process so as to form an encapsulant encapsulating the semiconductor chip, the interface layer, the first and second heat dissipating elements, wherein the upper surface of the heat dissipating portion of the first heat dissipating element is exposed from the encapsulant;
cutting the encapsulant along edges of the interface layer, wherein the cutting depth reaches at least the same level as the position of the interface layer; and
performing a removing process for removing the encapsulant located on the interface layer.

19. The method of claim 18, wherein the chip carrier is one of a substrate and a leadframe, and the semiconductor chip is electrically connected to the chip carrier through one of a flip-chip method and a wire bonding method.

20. The method of claim 19, wherein if the semiconductor chip is electrically connected to the chip carrier through the flip-chip method, the heat dissipating element having the interface layer is directly disposed on the non-active surface of the semiconductor chip; on the other hand, if the semiconductor chip is electrically connected to the chip carrier through bonding wires, a material layer can be disposed on the active surface of the semiconductor chip and then the heat dissipating element having the interface layer is disposed on the material layer.

21. The method of claim 20, wherein the material layer is one of a scraped chip and a heat dissipating element.

22. The method of claim 18, wherein the interface layer can be made of a material which makes the adhesion between the interface layer and the encapsulant greater than that between the interface layer and the second heat dissipating element such that both the interface layer and the encapsulant located on the interface layer can be removed through the removing process for exposing the surface of the second heat dissipating element.

23. The method of claim 22, wherein the interface layer is one of a tape, an epoxy resin and an organic layer.

24. The method of claim 18, wherein the interface layer is made of a material which makes the adhesion between the interface layer and the second heat dissipating element greater than that between the interface layer and the encapsulant such that only the encapsulant located on the interface layer is removed through the removing process for exposing the interface layer.

25. The method of claim 24, wherein the interface layer is a metal layer.

26. The method of claim 18, wherein the heat dissipating portion of the first heat dissipating element is 0.1 to 0.3 mm higher than the interface layer, and preferably, the heat dissipating portion of the first heat dissipating element is 0.15 mm higher than the interface layer.

27. The method of claim 18, wherein during the molding process, the chip carrier integrated with the semiconductor chip, the first heat dissipating element, the second heat dissipating element and the interface layer is disposed inside a mold cavity of a packaging mold so as to form the encapsulant, wherein the height of the heat dissipating portion of the first heat dissipating element is 0.05 to 0.1 mm greater than the depth of the mold cavity of the packaging mold, and correspondingly the interface layer is lower than the depth of the mold cavity, therefore, the first heat dissipating element can be abutted against the mold cavity of the packaging mold and compressed 0.05 to 0.1 mm.

28. The method of claim 18, wherein by cutting the encapsulant around the interface layer, a recess is formed, depth of which is at least at the same level as the interface layer, and is preferably 0.05 to 0.1 mm deeper than the interface layer.

29. The method of claim 18, wherein by cutting the encapsulant around the interface layer, a recess is formed, spacing between the recess and the interface layer is less than 0.1 mm, preferably 0.05 mm.

30. The method of claim 1, wherein by cutting the encapsulant around the interface layer, a recess is formed, which can extend into the interface layer less than 0.1 mm, preferably 0.05 mm.

31. The method of claim 18, wherein the size of the opening is greater than that of the interface layer, and the distance therebetween is 0.05 to 0.3 mm, and preferably 0.1 mm.

32. The method of claim 18, the opening and lateral sides of the heat dissipating portion of the first heat dissipating element have stepped structure.

33. A heat sink package structure, comprising:
a chip carrier;
a semiconductor chip mounted to and electrically connected to the chip carrier;
a first heat dissipating element comprising a heat dissipating portion, a supporting portion extending downward from the heat dissipating portion, and an opening formed in the heat dissipating portion, wherein the first heat dissipating element is mounted on the chip carrier through the supporting portion thereof, and the semiconductor chip is received in the receiving portion constituted by the heat dissipating portion and the supporting portion of the first heat dissipating element; and
an encapsulant formed on the chip carrier for encapsulating the semiconductor chip and the first heat dissipating element, wherein a recess structure is formed in the encapsulant corresponding in position to the opening of the heat dissipating portion of the first heat dissipating element so as to expose the upper surface of the semiconductor chip.

34. The structure of claim 33, wherein an interface layer is further disposed on the exposed surface of the semiconductor chip.

35. The structure of claim 34, wherein the interface layer is a metal layer.

36. The structure of claim 33, wherein an external heat dissipating element is disposed on the exposed surface of the semiconductor chip.

37. The structure of claim 33, wherein a material layer is further disposed on the exposed surface of the semiconductor chip.

38. The structure of claim 37, wherein the material layer is one of a scraped chip and a heat dissipating element.

39. The structure of claim 33, wherein the chip carrier is one of a substrate and a leadframe, and the semiconductor chip is electrically connected to the chip carrier through one of a flip-chip method and a wire-bonding method.

40. The structure of claim 33, wherein the opening and lateral sides of the heat dissipating portion of the first heat dissipating element have stepped structure.

41. A heat sink package structure, comprising:
a chip carrier;
a semiconductor chip mounted to and electrically connected to the chip carrier;
a second heat dissipating element disposed on the semiconductor chip;
a first heat dissipating element comprising a heat dissipating portion, a supporting portion extending downward from the heat dissipating portion, and an opening formed in the heat dissipating portion, wherein the first heat dissipating element is mounted on the chip carrier through the supporting portion thereof, and the semiconductor chip is received in the receiving portion constituted by the heat dissipating portion and the supporting portion of the first heat dissipating element; and
an encapsulant formed on the chip carrier for encapsulating the semiconductor chip and the first and second heat dissipating elements, wherein a recess structure is formed in the encapsulant corresponding in position to the second heat dissipating element so as to at least expose the upper surface of the second heat dissipating element.

42. The structure of claim 41, wherein an interface layer is further disposed on the exposed surface of the second heat dissipating element.

43. The structure of claim 42, wherein the interface layer is a metal layer.

44. The structure of claim 41, wherein the chip carrier is one of a substrate and a leadframe, and the semiconductor chip is electrically connected to the chip carrier through one of a flip-chip method and a wire-bonding method.

45. The structure of claim 41, wherein a material layer is further disposed between the second heat dissipating element and the semiconductor chip.

46. The structure of claim 45, wherein the material layer is one of a scraped chip and a heat dissipating element.

47. The structure of claim 41, wherein the opening and lateral sides of the heat dissipating portion of the first heat dissipating element have stepped structure.
